(19) United States
(12) Patent Application Publication
(10) Pub. No.: US 2026/0255950 A1
(43) Pub. Date: Aug. 27, 2026

(54) HIGH BANDWIDTH MEMORY DEVICES, SYSTEMS, AND FABRICATION METHODS THEREOF

(71) Applicant: Yangtze Memory Technologies Holding Co., Ltd., Wuhan (CN)

(72) Inventors: Haijun HUANG, Wuhan (CN); Dongyu FAN, Wuhan (CN); Wenxi ZHOU, Wuhan (CN); Zhiliang XIA, Wuhan (CN); Zongliang HUO, Wuhan (CN)

(21) Appl. No.: 19/070,966

(22) Filed: Mar. 5, 2025

(30) Foreign Application Priority Data
Feb. 24, 2025 (CN) 202510206246.2

(51) Int. Cl. H10W 20/41; H10B 80/00; H10W 90/00; H10W 90/20

(52) U.S. Cl. CPC H10W 20/427; H10B 80/00; H10W 90/00; H10W 90/297

(57) ABSTRACT

The present disclosure relates to methods, devices, systems, and techniques for high bandwidth memory (HBM). A semiconductor device includes a first semiconductor structure having a first ground conductive layer and a first signal conductive layer, and the second semiconductor structure having a second ground conductive layer and a second signal conductive layer. The semiconductor device also includes a first group of at least one signal contact structures contacts the first signal conductive layer and at least one ground contact structures contacts the first ground conductive layer; a second group of at least one signal contact structures contacts the second signal conductive layer and at least one ground contact structures contacts the second ground conductive layer, and where at least one group of the first group or the second group include signal contact structures and ground contact structures arranged in an array.

### CROSS-REFERENCE TO RELATED APPLICATIONS

This application claims priority to Chinese Patent Application No. 202510206246.2, filed on February 24, 2025, which is hereby incorporated by reference in its entirety.

### TECHNICAL FIELD

The present disclosure relates to high bandwidth memory (HBM) systems and devices and fabrication methods thereof.

### BACKGROUND

Semiconductor devices, e.g., memory devices, can have various structures to increase a density of memory cells and lines on a chip. For example, three-dimensional (3D) memory devices are attractive due to their capability to increase an array density by stacking more layers within a similar footprint. A 3D memory device normally includes a memory array of memory cells and peripheral circuits for facilitating operations of the memory array.

A high bandwidth memory (HBM) uses stacked memory devices to enable effective data movement and access. While using less power in a smaller form factor, HBM devices can achieve higher bandwidth. HBM devices have been applied to high-performance graphics accelerators, network devices, high-performance datacenter, artificial intelligence (AI) and machine learning (ML) training, and various supercomputers.

### SUMMARY

The present disclosure describes methods, devices, systems and techniques for high bandwidth memory (HBM).

One aspect of the present disclosure features a semiconductor device. The semiconductor device includes a first semiconductor structure and a second semiconductor structure stacked along a first direction, where the first semiconductor structure includes a first ground conductive layer and a first signal conductive layer, and the second semiconductor structure includes a second ground conductive layer and a second signal conductive layer. The semiconductor device also includes a first group of signal contact structures and ground contact structures , where the first group extends into the first semiconductor structure along the first direction, at least one signal contact structure in the first group contacts the first signal conductive layer, and at least one ground contact structure in the first group contacts the first ground conductive layer; and a second group of signal contact structures and ground contact structures, where the second group extends from the first semiconductor structure into the second semiconductor structure along the first direction, at least one signal contact structure in the second group contacts the second signal conductive layer, and at least one ground contact structure in the second group contacts the second ground conductive layer, and where at least one group of the first group or the second group includes signal contact structures and ground contact structures arranged in an array; the array includes first signal contact structures and first ground contact structures arranged along a first line extending in a second direction perpendicular to the first direction; and the first ground contact structures are evenly spaced among the first signal contact structures.

In some implementations, each signal contact structure in the array is adjacent to a corresponding ground contact structure in the array, where a distance between the signal contact structure in the array and the corresponding ground contact structure in the array equals a pitch size of the array.

In some implementations, the pitch size is in a range between 0.5 micrometers (µm) and 10 µm, and a size of each signal contact structure or each ground contact structure in the array along the second direction is between 0.5 µm and 10 µm.

In some implementations, a same number of first signal contact structures are between any two adjacent first ground contact structures along the second direction.

In some implementations, the number is an integer between one and five.

In some implementations, the array further includes second signal contact structures and second ground contact structures arranged along a second line extending in the second direction, the second ground contact structures are evenly spaced among the second signal contact structures, and the second line is adjacent to the first line along a third direction perpendicular to the first direction and the second direction.

In some implementations, each of the first signal contact structures or each of the first ground contact structures is aligned with one of the second signal contact structures or one of the second ground contact structures along the third direction.

In some implementations, each of the first signal contact structures and the first ground contact structures is between either two adjacent ones of the second signal contact structures or one of the second signal contact structures and one of the second ground contact structures along the second direction.

In some implementations, the semiconductor device further includes a third semiconductor structure including a third ground conductive layer and a third signal conductive layer, where the second semiconductor structure is between the first semiconductor structure and the third semiconductor structure along the first direction; and a third group of signal contact structures and ground contact structures, where the third group extends from the first semiconductor structure into the third semiconductor structure along the first direction, at least one signal contact structure in the third group contacts the third signal conductive layer, at least one ground contact structure in the third group contacts the third ground conductive layer, the third group includes third signal contact structures and third ground contact structures arranged along a third line extending in the second direction, and the third ground contact structures are evenly spaced among the third signal contact structures.

In some implementations, the semiconductor device further includes a first bonding structure between the first semiconductor structure and the second semiconductor structure, where the first semiconductor structure and the second semiconductor structure are bonded through the first bonding structure; and a second bonding structure between the second semiconductor structure and the third semiconductor structure, where the second semiconductor structure and the third semiconductor structure are bonded through the second bonding structure.

Another aspect of the present disclosure features a semiconductor device. The semiconductor device includes a first semiconductor structure and a second semiconductor structure stacked along a first direction, where the first semiconductor structure includes a first substrate, a first ground conductive layer and a first signal conductive layer, the first substrate includes a first dielectric structure and a semiconductor material surrounding the first dielectric structure, and the second semiconductor structure includes a second ground conductive layer and a second signal conductive layer; a first group of signal contact structures and ground contact structures, where the first group extends into the first semiconductor structure along the first direction, the ground contact structures in the first group are evenly spaced among the signal contact structures in the first group , at least one signal contact structure in the first group contacts the first signal conductive layer, and at least one ground contact structure in the first group contacts the first ground conductive layer; and a second group of signal contact structures and ground contact structures, where the second group extends from the first semiconductor structure through the first dielectric structure and into the second semiconductor structure along the first direction, the ground contact structures in the second group are evenly spaced among the signal contact structures in the second group, at least one signal contact structure in the second group contacts the second signal conductive layer, and at least one ground contact structure in the second group contacts the second ground conductive layer.

In some implementations, the second semiconductor structure includes a second substrate, the second substrate includes a second dielectric structure and a semiconductor material surrounding the second dielectric structure, and the semiconductor device further includes a third semiconductor structure including a third ground conductive layer and a third signal conductive layer, where the second semiconductor structure is between the first semiconductor structure and the third semiconductor structure along the first direction; and a third group of signal contact structures and ground contact structures, where the third group extends from the first semiconductor structure through the first dielectric structure and the second dielectric structure and into the third semiconductor structure along the first direction, the signal contact structures in the third group are evenly spaced among the signal contact structures in the third group, at least one signal contact structure in the third group contacts the third signal conductive layer, and at least one ground contact structure in the third group contacts the third ground conductive layer.

In some implementations, the first dielectric structure and the second dielectric structure have a same size along a second direction perpendicular to the first direction and are aligned along the first direction.

In some implementations, the first semiconductor structure and the second semiconductor structure are bonded through a dielectric bonding structure .

In some implementations, the at least one of the first semiconductor structure or the second semiconductor structure is a dynamic random-access memory (DRAM) device.

In some implementations, the DRAM device includes an array structure and a peripheral structure, the array structure includes an array of DRAM cells, at least one DRAM cell of the array structure includes a transistor and a capacitor, and the peripheral structure includes a peripheral circuit configured to control the array of DRAM cells.

In some implementations, the array structure and the peripheral structure are bonded through a bonding structure, and the bonding structure includes conductive bonding contacts and a dielectric material isolating the conductive bonding contacts.

In some implementations, the signal contact structures and the ground contact structures in at least one of the first group or the second group are arranged in an array, each signal contact structure of the signal contact structures is adjacent to a corresponding ground contact structure of the ground contact structures, where a distance between the signal contact structure and the corresponding ground contact structure equals a pitch size of the array.

A further aspect of the present disclosure features a semiconductor device. The semiconductor device includes a first semiconductor structure and a second semiconductor structure stacked along a first direction, where the first semiconductor structure includes a first substrate, a first ground conductive layer and a first signal conductive layer, and the second semiconductor structure includes a second ground conductive layer and a second signal conductive layer; a first group of signal contact structures and ground contact structures, where the first group extends into the first semiconductor structure along the first direction, the ground contact structures in the first group are evenly spaced among the signal contact structures in the first group, at least one signal contact structure in the first group contacts the first signal conductive layer, and at least one ground contact structure in the first group contacts the first ground conductive layer; and a second group of signal contact structures and ground contact structures, where the second group extends from the first semiconductor structure through the first substrate and into the second semiconductor structure along the first direction, the ground contact structures in the second group are evenly spaced among the signal contact structures in the second group, at least one signal contact structure in the second group contacts the second signal conductive layer, and at least one ground contact structure in the second group contacts the second ground conductive layer.

In some implementations, the signal contact structures and the ground contact structures in at least one of the first group or the second group are arranged in an array, each signal contact structure of the signal contact structures is adjacent to a corresponding ground contact structure of the ground contact structures, where a distance between the signal contact structure and the corresponding ground contact structure equals a pitch size of the array.

The details of one or more implementations of the subject matter of this present disclosure are set forth in the accompanying drawings and the description below. Other features, aspects, and advantages of the subject matter will become apparent from the description, the drawings, and the claims.

### BRIEF DESCRIPTION OF THE DRAWINGS

The accompanying drawings, which are incorporated herein and form a part of the present disclosure, illustrate aspects of the present disclosure and, together with the description, further serve to explain the principles of the present disclosure and to enable a person of ordinary skill in the pertinent art to make and use the present disclosure.

FIGS. 1A - 1B illustrate cross-sectional view of example semiconductor devices, according to some aspects of the present disclosure.

FIG. 1C illustrates a top view of an example semiconductor device, according to some aspects of the present disclosure.

FIG. 2A illustrates a top view of an example semiconductor device, according to some aspects of the present disclosure.

FIG. 2B illustrates a cross-sectional view of an example semiconductor device, according to some aspects of the present disclosure.

FIGS. 3A-3C illustrate top views of an example semiconductor device, according to some aspects of the present disclosure.

FIGS. 4A-4C illustrate top views of an example semiconductor device, according to some aspects of the present disclosure.

FIG. 5 illustrates a block diagram of an example system having one or more semiconductor devices.

Like reference numbers and designations in the various drawings indicate like elements. It is also to be understood that the various exemplary implementations shown in the figures are merely illustrative representations and are not necessarily drawn to scale.

### DETAILED DESCRIPTION

Due to the increased demand for cheaper memory devices with higher density, a memory device (e.g., high bandwidth memory (HBM)) can be designed with an increased array density by stacking multiple layers of the memory device on top of each other. The high array density and layer stacking structure of HBM memory require more signal contact structures to connect to each layer. The large number of signal contact structures may pose challenges in signal integrity. Current implementations to reduce signal noise and maintain signal integrity involve increasing the number of shielding structures (e.g., ground contact structures) at certain fixed locations in the memory chip. This approach may pose several challenges in integrating the ground contact structures. First, a large number of ground contact structures around the signal contact structures are required to maintain signal integrity and ensure low loss between memory communications. However, the large number of ground contact structures will take up a significant chip area, increasing fabrication costs and reducing the active area. Second, the fixed location of the ground contact structures can lead to varying distances between the ground contact structures and the signal contact structures, which may reduce signal integrity when transferring signals between different signal contact structures on the chip. Therefore, new techniques to form and arrange the ground contact structures for the contact structures that can reduce fabrication costs and occupy less area in the memory device are desirable.

In one or more implementations of the present disclosure, an example semiconductor device is provided. The semiconductor device can include a first semiconductor structure and a second semiconductor structure stacked along a first direction. The first semiconductor structure includes a first ground conductive layer and a first signal conductive layer, and the second semiconductor structure includes a second ground conductive layer and a second signal conductive layer. The semiconductor device also includes a first group of signal contact structures and ground contact structures, where the first group extends into the first semiconductor structure along the first direction. At least one signal contact structure in the first group contacts the first signal conductive layer, and at least one ground contact structure in the first group contacts the first ground conductive layer. The semiconductor device further includes a second group of signal contact structures and ground contact structures, where the second group extends from the first semiconductor structure into the second semiconductor structure along the first direction. At least one signal contact structure in the second group contacts the second signal conductive layer, and at least one ground contact structure in the second group contacts the second ground conductive layer. At least one group of the first group or the second group includes signal contact structures and ground contact structures arranged in an array. The array includes first signal contact structures and first ground contact structures arranged along a first line extending in a second direction perpendicular to the first direction, and the first ground contact structures are evenly spaced among the first signal contact structures.

Implementations of the present disclosure can provide one or more of the following technical advantages and/or benefits. First, the different groups of signal contact structures and ground contact structures ensure that at least one ground contact structure is connected to the ground conductive layer of each semiconductor structure. In other words, the ground contact structures connected to the ground conductive layers of each semiconductor structure can help reduce noise in the signal contact structures during a single transfer process. Second, the signal contact structures and ground contact structures in each group are evenly spaced, which can help create an optimized layout to maintain signal integrity. Third, the same number of signal contact structures are placed between any two adjacent ground contact structures in each group, which can help optimize the arrangement of the ground contact structures among the signal contact structures, reduce the number of ground contact structures needed to maintain signal integrity, and reduce the chip size required for the ground contact structures. Fourth, a dielectric wall can be formed in the substrate of each of the semiconductor structures. The dielectric wall can help to simplify the etching process to form the signal contact structures and the ground contact structures, which can reduce the fabrication cost.

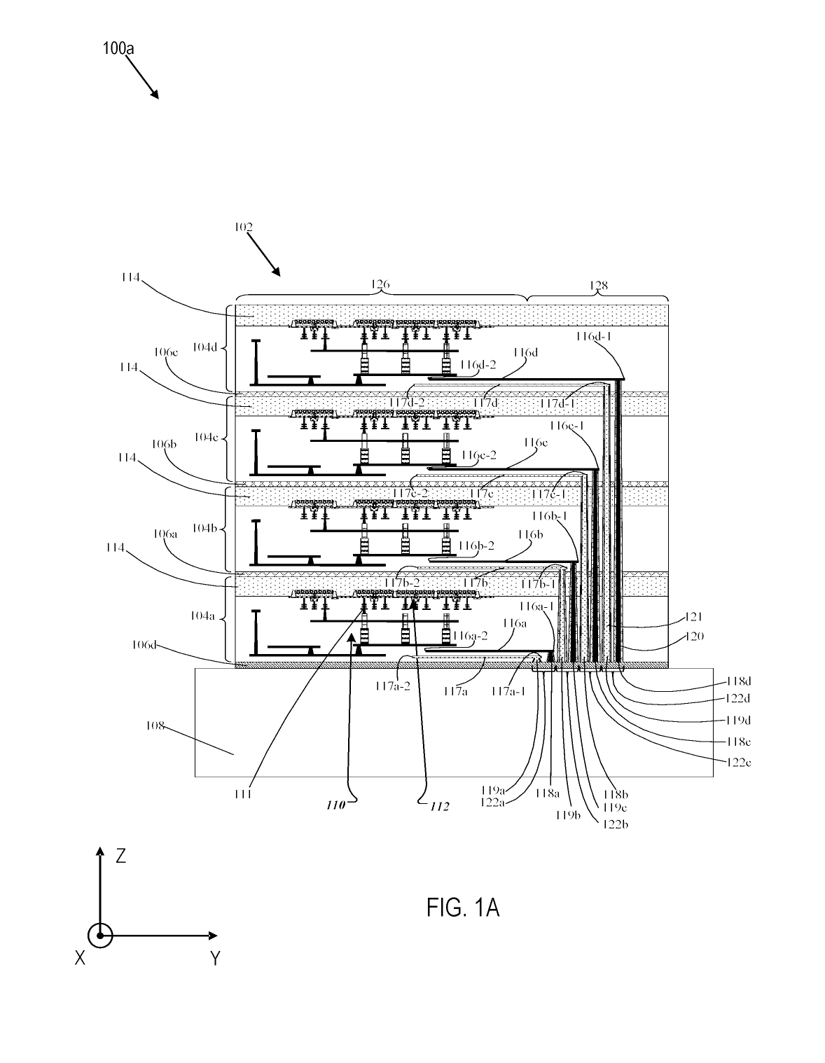

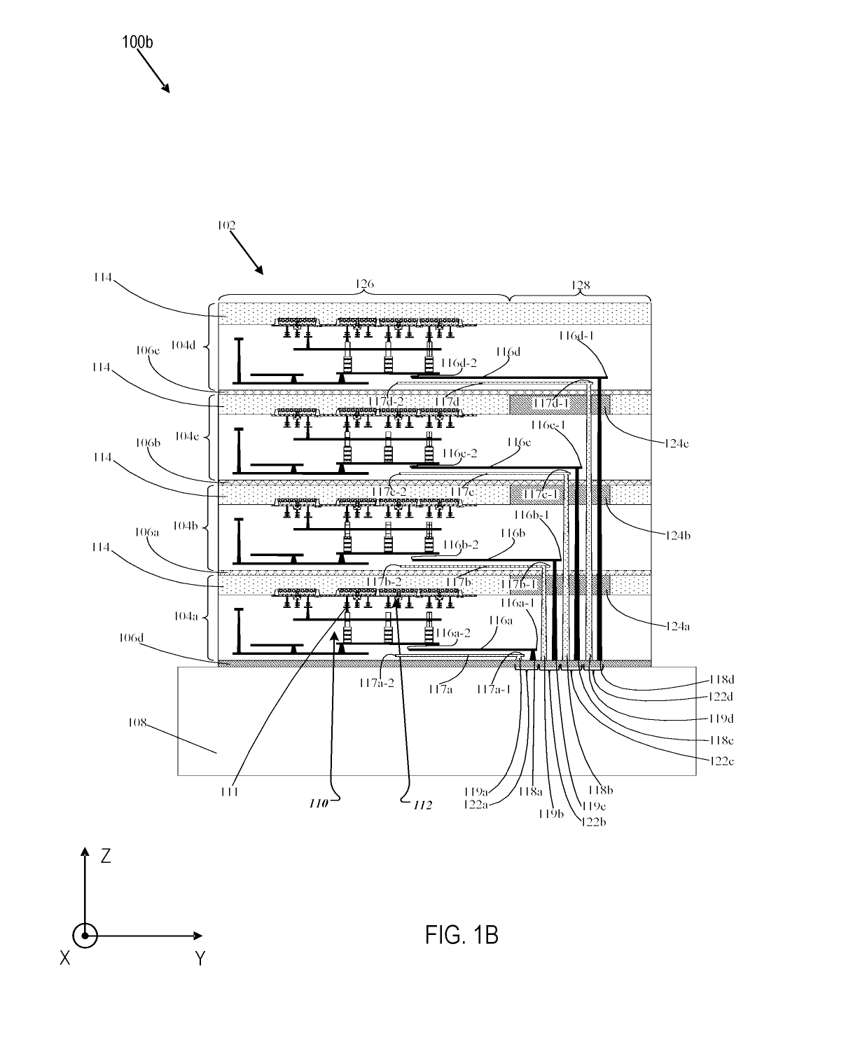

FIG. 1A illustrate a cross-sectional view of an example semiconductor device 100a, according to some aspects of the present disclosure. The semiconductor device 100a can be a memory device, e.g., an HBM. It is noted that X, Y, and Z axes (also referred to as X, Y, and Z directions) are included in FIG. 1A to further illustrate the spatial relationship of various components in a semiconductor device. A substrate of the semiconductor device includes two lateral surfaces extending laterally in the X-Y plane: a top surface on the front side of a wafer on which a component of the semiconductor device can be formed, and a bottom surface on the backside opposite to the front side of the wafer. The Z direction is perpendicular to both the X and Y directions. As used herein, whether one component (e.g., a layer or a device) is “on,” “above,” or “below” another component (e.g., a layer or a device) of the semiconductor device is determined relative to the substrate of the semiconductor device in the Z direction (the vertical direction perpendicular to the X-Y plane, e.g., the thickness direction of the substrate) when the substrate is positioned in the lowest plane of the semiconductor device in the Z direction. The same notion for describing the spatial relationships is applied throughout the present disclosure.

As shown in FIG. 1A, the semiconductor device 100a includes a stack 102 of semiconductor structures 104a - 104d. Each of the semiconductor structures 104a - 104d can be a dynamic random-access memory (DRAM) device. The semiconductor structures 104a - 104d are stacked (e.g., sequentially) along a vertical direction (e.g., the Z direction).

The semiconductor device 100a includes bonding structures 106a - 106c (also refer as dielectric bonding structure) As shown in FIG. 1A, each of the bonding structures 106a - 106c is between two of semiconductor structures 104a - 104d. For example, as shown in FIG. 1A, the semiconductor structures 104a and 104b are bonded through bonding structure 106a. The semiconductor structures 104b and 104c are bonded through bonding structure 106b. The semiconductor structures 104c and 104d are bonded through bonding structure 106c. Each of the bonding structures 106a - 106c can include a top bonding layer and a bottom bonding layer bonded at a bonding interface. Each of the top bonding layer and the bottom bonding layer can include a dielectric material (including, but not limited to, silicon oxide, silicon nitride, silicon oxynitride, low-k dielectrics, or any combination thereof) and can exclude a conductive bonding contact.

The semiconductor structure 104a can be bonded on top of the semiconductor structure 104b in a face-to-face manner through the bonding structure 106a. Bonding interface is disposed between the top bonding layer and the bottom bonding layer as a result of direct bonding (e.g., dielectric-dielectric bonding), which forms bonding between surfaces without using intermediate layers, such as solder or adhesives. In some implementations (not shown in FIG. 1A), for example, when the dielectric material of the top bonding layer and the dielectric material of the bottom bonding layer are different materials, bonding interface can be a visible layer with a certain thickness that includes a top surface of the bottom bonding layer and a bottom surface of the top bonding layer. In some implementations, as shown in the example of FIG. 1A, when the dielectric material of the top bonding layer and the dielectric material of the bottom bonding layer are the same material, bonding interface may not be visible and the top bonding layer and the bottom bonding layer may form a continuous bonding structure 106a.

In some implementations, as shown in FIG. 1A, the stack 102 of the semiconductor structures 104a - 104d are stacked on a base die 108 (also referred to as a logic die or a buffer die), which can include buffer circuitry and test logic for semiconductor device 100a. Base die 108 can be configured to provide physical layer communication protocols (e.g., IEEE-1500) between semiconductor device 100a and a computing die. Base die 108 can be configured to transmit data between semiconductor device 100a and computing die based on control commands and addresses from computing die. In some implementations, the base die 108 is bonded to the stack 102 through a bonding structure 106d.

As shown in FIG. 1A, each of the semiconduction structures 104a - 104d in the stack 102 can include a memory array structure 110 and a peripheral structure 112. The memory array structure 110 can include an array of DRAM cells. At least one DRAM cell of the array of the DRAM cells can include a transistor and a capacitor. In some implementations, the peripheral structure 112 includes a peripheral circuit configured to control the array of the DRAM cells. In some implementations, as shown in FIG. 1A, the memory array structure 110 and the peripheral structure 112 are bonded through a bonding structure 111. The bonding structure 111 can include conductive bonding contacts and a dielectric material isolating the conductive bonding contacts. Each of the semiconductor structures 104a - 104d can include a substrate 114, which can include silicon (e.g., single crystalline silicon, c-Si), SiGe, GaAs, Ge, SOI, or any other suitable materials. The peripheral structure 112 can be formed on or in the substrate 114 as shown in FIG. 1A. In some implementations, the substrate can be thinned down or removed in a later fabrication process. For example, as shown in FIG. 1A, the substrate 114 of the semiconductor structure 104a is thinned down. In some implementations, the substrate 114 of some semiconductor structure (e.g., semiconductor structure 104d as shown in FIG. 1A) can be thicker than that of other semiconductor structures to provide support for the stack 102.

As shown in FIG. 1A, each of the semiconductor structures 104a - 104d can also include signal conductive layers 116. For example, the semiconductor structure 104a can include a first signal conductive layer 116a, the semiconductor structure 104b can include a second signal conductive layer 116b and the semiconductor structure 104c can include a third signal conductive layer 116c. In some implementations, the number of the semiconductor structures 104 stacked on top of each other is more than 3 and each of the semiconductor structures 104 can include a corresponding signal conductive layer 116. For example, as shown in FIG. 1A, the semiconductor structure 104d can include a fourth signal conductive layer 116d.

As shown in FIG. 1A, the signal conductive layers 116a - 116d of the semiconductor structures 104a - 104d of the semiconductor device 100b are arranged in a staircase structure. For example, as shown in FIG. 1A, a first end 116a-1 of the first signal conductive layer 116a, a first end 116b-1 of the second signal conductive layer 116b, a first end 116c-1 of the third signal conductive layer 116c, and a first end 116d-1 of the fourth signal conductive layer 116d are offset along the Y direction; a second end 116a-2 of the first signal conductive layer 116a, a second end 116b-2 of the second signal conductive layer 116b, a second end 116c-2 of the third signal conductive layer 116c, and a second end 116d-2 of the fourth signal conductive layer 116d are aligned along the Z direction. In some implementations, as shown in FIG. 1A, along the Y direction, a length of the first signal conductive layer 116a is smaller than a length of the second signal conductive layer 116b, the length of the second signal conductive layer 116b is smaller than a length of the third signal conductive layer 116c, and the length of the third signal conductive layer 116c is smaller than a length of the fourth signal conductive layer 116d. In some implementations, the first signal conductive layer 116a is included in an interconnect layer of the semiconductor structure 104a. The second signal conductive layer 116b is included in an interconnect layer of the semiconductor structure 104b. The third signal conductive layer 116c is included in an interconnect layer of the semiconductor structure 104c. The fourth signal conductive layer 116d is included in an interconnect layer of the semiconductor structure 104d. An interconnect layer can include interconnects (also referred to herein as “contacts”), including lateral interconnect lines and vertical interconnect access (VIA) contacts. As used herein, the term “interconnects” can broadly include any suitable types of interconnects, such as middle-end-of-line (MEOL) interconnects and back-end-of-line (BEOL) interconnects. For example, each of the signal conductive layers 116 can be or can include one or more interconnects in a corresponding interconnect layer. The interconnect layer can further include one or more interlayer dielectric (ILD) layers (also known as “intermetal dielectric (IMD) layers”) in which the interconnect lines and VIA contacts can form. That is, the interconnect layer can include interconnect lines and VIA contacts in multiple ILD layers. The interconnect lines and VIA contacts in the interconnect layer can include conductive materials including, but not limited to, tungsten (W), cobalt (Co), copper (Cu), aluminum (Al), silicides, or any combination thereof. The ILD layers in the interconnect layer can include dielectric materials including, but not limited to, silicon oxide, silicon nitride, silicon oxynitride, low dielectric constant (low-k) dielectrics, or any combination thereof.

Each of the semiconductor structures 104a - 104d can also include ground conductive layers 117. In each of the semiconductor structures 104a – 104d, the ground conductive layer 117 is spaced from the signal conductive layer 116. For example, as shown in FIG. 1A, the semiconductor structure 104a can include a first ground conductive layer 117a that extends along the Y direction and spaced from the first signal conductive layer 116a, the semiconductor structure 104b can include a second ground conductive layer 117b that extends along the Y direction and spaced from the second signal conductive layer 116b and the semiconductor structure 104c can include a third ground conductive layer 117c that extends along the Y direction and spaced from the third signal conductive layer 116c. In some implementations, the number of the semiconductor structures 104 stacked on top of each other is more than 3 and each of the semiconductor structures 104 can include a corresponding ground conductive layer 117. For example, as shown in FIG. 1A, the semiconductor structure 104d can include a fourth ground conductive layer 117d that extends along the Y direction and spaced from the fourth signal conductive layer 116d.

As shown in FIG. 1A, the ground conductive layers 117a - 117d of the semiconductor structures 104a - 104d of the semiconductor device 100b are arranged in a staircase structure. For example, as shown in FIG. 1A, a first end 117a-1 of the first ground conductive layer 117a, a first end 117b-1 of the second ground conductive layer 117b, a first end 117c-1 of the third ground conductive layer 117c, and a first end 117d-1 of the fourth ground conductive layer 117d are offset along the Y direction; a second end 117a-2 of the first ground conductive layer 117a, a second end 117b-2 of the second ground conductive layer 117b, a second end 117c-2 of the third ground conductive layer 117c, and a second end 117d-2 of the fourth ground conductive layer 117d are aligned along the Z direction. In some implementations, as shown in FIG. 1A, along the Y direction, a length of the first ground conductive layer 117a is smaller than a length of the second ground conductive layer 117b, the length of the second ground conductive layer 117b is smaller than a length of the third ground conductive layer 117c, and the length of the third ground conductive layer 117c is smaller than a length of the fourth ground conductive layer 117d.

The semiconductor device 100a can further include multiple signal contact structures 118 and ground contact structures 119 that extend along the Z direction. The multiple signal contact structures 118 and the ground contact structures 119 are separated from each other along the Y direction. For example, as shown in FIG. 1A, the multiple signal contact structures 118 can include a first signal contact structure 118a, a second signal contact structure 118b and a third signal contact structure 118c. The multiple ground contact structures 119 can include a first ground contact structure 119a, a second ground contact structure 119b and a third ground contact structure 119c. In some implementations, the multiple signal contact structures 118 and the multiple ground contact structures 119 are arranged into a plurality of groups 122, where each of the groups 122 of the multiple signal contact structures 118 and the multiple ground contact structures 119 are connected to the signal conductive layers 116 and the ground conductive layers 117 of a corresponding semiconductor structures 104a – 104c. For example, as shown in FIG. 1A, a first group 122a of the multiple signal contact structures 118 and the multiple ground contact structures 119 can include at least one first signal contact structures 118a and at least one first ground contact structures 119a that extend into the semiconductor structure 104a, where the at least one first signal contact structures 118a is connected to the first signal conductive layer 116a and the at least one first ground contact structures 119a is connected to the first ground conductive layer 117a. A second group 122b of the multiple signal contact structures 118 and the multiple ground contact structures 119 can include at least one second signal contact structures 118b and at least one second ground contact structures 119b that extend into the semiconductor structure 104b, where the at least one second signal contact structures 118b is connected to the second signal conductive layer 116b and the at least one second ground contact structures 119b is connected to the second ground conductive layer 117b. A third group122c of the multiple signal contact structures 118 and the multiple ground contact structures 119 can include at least one third signal contact structures 118c and at least one third ground contact structures 119c that extend into the semiconductor structure 104c, where the at least one third signal contact structures 118c is connected to the third signal conductive layer 116c and the at least one third ground contact structures 119c is connected to the third ground conductive layer 117c. In some implementations, the number of the semiconductor structures 104 stacked on top of each other is more than 3 and the groups 122 of the multiple signal contact structures 118 and the multiple ground contact structures 119 further include a fourth group 122d that includes at least one fourth signal contact structures 118d and at least one fourth ground contact structures 119d that extend into the semiconductor structure 104d, where the at least one fourth signal contact structures 118d is connected to the fourth signal conductive layer 116d and the at least one fourth ground contact structures 119d is connected to the fourth ground conductive layer 117d.

In some implementations, the groups 122 of the multiple signal contact structures 118 and the multiple ground contact structures 119 can be arranged in an array. In some implementations, each of the signal contact structures 118 in the array is adjacent to a corresponding ground contact structure 119 in the array, where a distance between the signal contact structure 118 in the array and the corresponding ground contact structure 119 in the array equals a pitch size of the array. In some implementations, the pitch size of the array is in a range between 0.5 micrometers (µm) and 10 µm, and a size of each of the signal contact structures 118 or each of the ground contact structures 119 in the array along the Y direction is between 0.5 µm and 10 µm. For example, the first group 122a of the at least one first signal contact structures 118a and the at least one first ground contact structures 119a can be arranged along a first line of the array extending in a horizontal direction (e.g., the Y direction) perpendicular to the Z direction. In some implementations, the first ground contact structure 119a in the first group 122a are evenly spaced among the first signal contact structure 118a in the first group 122a. For example, a same number of the first signal contact structures 118a are between any two adjacent first ground contact structures 119a along the Y direction. The second group 122b of the at least one second signal contact structures 118b and the at least one second ground contact structures 119b can be arranged along a second line of the array extending along the Y direction, where the second ground contact structures 119b are evenly spaced among the second signal contact structures 118b, and the second line of the array is adjacent to the first line of the array along a second horizontal direction (e.g., the X direction) perpendicular to the first direction. The third group 122c of the at least one third signal contact structures 118c and the at least one third ground contact structures 119c can be arranged along a third line of the array extending along the Y direction, where the third ground contact structures 119c are evenly spaced among the third signal contact structures 118c, and the second line of the array is between the third line and the first line of the array along the X direction. In some implementations, the number of the semiconductor structures 104 stacked on top of each other is more than 3 and the groups 122 of the multiple signal contact structures 118 and the multiple ground contact structures 119 further include a fourth group 122d that includes at least one fourth signal contact structures 118d and at least one fourth ground contact structures 119d that extend into the semiconductor structure 104d. The fourth group 122d of the at least one fourth signal contact structures 118d and the at least one fourth ground contact structures 119d can be arranged along a fourth line of the array extending along the Y direction, where the fourth ground contact structures 119d are evenly spaced among the fourth signal contact structures 118d, and the third line of the array is between the second line and the fourth line of the array along the X direction.

As shown in FIG. 1A, each of the signal contact structures 118 can include a first dielectric outer layer 120 that surrounds the signal contact structure 118 along the Y direction. Each of the ground contact structures 119 can include a second dielectric outer layer 121 that surrounds the ground contact structure 119 along the Y direction. The first dielectric outer layer 120 and the second dielectric outer layer 121 can be used to insulate the signal contact structures 118 and the ground contact structures 119 from other components of the semiconductor structures 104a – 104b along the Y direction.

In some implementations, the signal contact structures 118 can be used as a signal transmission channel between the memory devices in each of the semiconductor structures 104. The ground contact structures 119 can be used as ground contacts for the signal contact structures 118, which reduce the noise and interference generated by the signal contact structures 118 during a signal transmission process and improve signal integrity during the device operation. The ground contact structures 119 are placed adjacent to the signal contact structures 118 to reduce the chip area and increase the effective active area ratio of a memory device.

It is understood that the example semiconductor device 100a as shown in FIG. 1A is for illustration purpose and is not intended to be construed in a limiting sense. For example, the semiconductor structures 104 stacked on top of each other is not limited to 4 structures and any number of semiconductor structures 104 can be stacked on top of each other in the semiconductor device 100a. For each of the semiconductor structures 104, the semiconductor device 100a includes the signal contact structures 118 that contact the corresponding signal conductive layer 116 of each of the semiconductor structures 104 and the ground contact structures 119 that contact the corresponding ground conductive layer 117 of each of the semiconductor structures 104.

In some implementations, the semiconductor device 100a can include a device region 126 and a connection region 128. As shown in FIG. 1A, the device region 126 of the semiconductor device 100a can include the memory array structure 110 and the peripheral structure 112 of the semiconductor structures 104a – 104b. The connection region 128 of the semiconductor device 100a can include the signal conductive layers 116, the ground conductive layers 117 the signal contact structures 118 that connected to the corresponding signal conductive layers 116, and the ground contact structures 119 that connected to the corresponding ground conductive layers 117 of the semiconductor structures 104a – 104b.

In some implementations, the signal contact structures 118 and the ground contact structures 119 can be formed by etching a first portion of the semiconductor structures 104a – 104d to form a first contact holes and etching a second portion of the semiconductor structures 104a – 104d to from a second contact holes. The first contact holes and the second contact holes are spaced from each other along the Y direction. The first contact holes are in contact with the signal conductive layers 116 of the corresponding semiconductor structures 104a – 104d. The second contact holes are in contact with the ground conductive layers 117 of the corresponding semiconductor structures 104a – 104d.

In some implementations, the forming of the first contact holes and the second contact holes can take several etching processes. In some implementations, the substrate 114 can include a semiconductor material (e.g., Si) and the semiconductor structures 104a – 104d can a dielectric filling having a dielectric material (e.g., SiO₂) that is different from the semiconductor material of the substrate 114. The etchants for etching the semiconductor material in the substrate 114 and the dielectric material in the dielectric filling of the semiconductor structures 104a – 104d are different. For example, a first etching process with a first etchant is used to etch the dielectric filling in the semiconductor structure 104a, a second etching process with a second etchant is used to etch through the substrate 114 of the semiconductor structure 104a, and a third etching process with the first etchant is used to etch a portion of the dielectric filling in the semiconductor structure 104b to form the first contact holes that are in contact with the second signal conductive layer 116b of the semiconductor structure 104b.

The signal structures 118 are formed by filling a first conductive material surrounded by a dielectric material in the first contact holes. The ground contact structures 119 are formed by filling a second conductive material surrounded by the dielectric material in the second contact holes. In some implementations, the first conductive material can be any conductive material including, but not limited to, W, Co, Cu, Al, doped silicon, silicides, or any combination thereof. The second conductive material can be any conductive material including, but not limited to, W, Co, Cu, Al, doped silicon, silicides, or any combination thereof. The dielectric material can be any dielectric material including, but not limited to, silicon oxide, silicon nitride, silicon oxynitride, low-k dielectrics, or any combination thereof. In some implementations, the first conductive material can be same as the second conductive material. For example, the first conductive material and the second conductive material both can be W.

FIG. 1B illustrates a cross-sectional view of an example semiconductor device 100b. The semiconductor device 100b can be similar to the semiconductor device 100a of FIG. 1A, except the substrate 114, the signal contact structures 118, and the ground contact structures 119 of the semiconductor device 100b have different structures compared to the semiconductor device 100a of FIG. 1A.

As shown in FIG. 1B, the substrate 114 of each of the semiconductor structures 104a – 104c can include a dielectric structure 124. The dielectric structure 124 is sometime refer as a well structure inside the substrate 114. For example, as shown in FIG. 1B, the substrate 114 of the semiconductor structure 104a includes a first dielectric structure 124a. The substrate 114 of the semiconductor structure 104b includes a second dielectric structure 124b. The substrate 114 of the semiconductor structure 104c includes a third dielectric structure 124c. The substrate 114 of the semiconductor structures 104a – 104c can include a semiconductor material such as poly-Si. The first dielectric structure 124a, the second dielectric structure 124b, and the third dielectric structure 124c can include a dielectric material such as SiO₂. The first dielectric structure 124a can be surrounded (e.g., along a direction perpendicular to the Z direction) by the semiconductor material of the substrate 114 of the semiconductor structure 104a. Similarly, the second dielectric structure 124b can be surrounded (e.g., along a direction perpendicular to the Z direction) by the semiconductor material of the substrate 114 of the semiconductor structure 104b, and the third dielectric structure 124c can be surrounded (e.g., along a direction perpendicular to the Z direction) by the semiconductor material of the substrate 114 of the semiconductor structure 104c. In some implementations, each of the dielectric structures 124a, 124b, and 124c may not be fully surrounded by the semiconductor material of the substrate 114 of the corresponding the semiconductor structure (e.g., 104a, 104b, or 104c). For example, the dielectric structures 124a, 124b, and 124c can be adjacent to (e.g., along the Y direction) the semiconductor material of the substrate 114 of the semiconductor structures 104a, 104b, and 104c, respectively. The first dielectric structure 124a, the second dielectric structure 124b, and the third dielectric structure 124c can be used to isolate the signal contact structures 118 and the ground contact structures 119 from the substrate 114 of the semiconductor structures 104a – 104c. In some implementations, the first dielectric structure 124a, the second dielectric structure 124b, and the third dielectric structure 124c have a same size along the Y direction.

The semiconductor device 100b includes the first group 122a of the first signal contact structures 118a and the first ground contact structures 119a extends into the semiconductor structure 104a along the Z direction, the first ground contact structures 119a in the first group 122a are evenly spaced among the first signal contact structures 118a in the first group 122a. At least one first signal contact structure 118a in the first group 122a contacts the first signal conductive layer 116a, and at least one first ground contact structure 119a in the first group 122a contacts the first ground conductive layer 117a. The semiconductor device 100b also includes the second group 122b of the second signal contact structures 118b and the second ground contact structures 119b, the second group 122b extends from the semiconductor structure 104a through the first dielectric structure 124a and into the semiconductor structure 104b along the Z direction, the second ground contact structures 119b in the second group 122b are evenly spaced among the second signal contact structures 118b in the second group 122b. At least one second signal contact structure 118b in the second group 122b contacts the second signal conductive layer 116b, and at least one second ground contact structure 119b in the second group 122b contacts the second ground conductive layer 117b. In some implementations, as shown in FIG. 1B, the semiconductor device 100b can further include the third group 122c of the third signal contact structures 118c and the third ground contact structures 119c. The third group 112c extends from the semiconductor structure 104a through the first dielectric structure 124a and the second dielectric structure 124b and into the semiconductor structure 104c along the Z direction, the third ground contact structures 119c in the third group 122c are evenly spaced among the third signal contact structures 118c in the third group 122c. At least one third signal contact structure 118c in the third group 122c contacts the third signal conductive layer 116c, and at least one third ground contact structure 119c in the third group 122c contacts the third ground conductive layer 117c. In some implementations, the number of the semiconductor structures 104 stacked on top of each other is more than 3 and the groups 122 of the multiple signal contact structures 118 and the multiple ground contact structures 119 further include a fourth group 122d of the fourth signal contact structures 118d and the fourth ground contact structures 119d. The fourth group 112d extends from the semiconductor structure 104d through the first dielectric structure 124a, the second dielectric structure 124b, and the third dielectric structure 124c and into the semiconductor structure 104d along the Z direction, the fourth ground contact structures 119d in the fourth group 122d are evenly spaced among the fourth signal contact structures 118d in the fourth group 122d. At least one fourth signal contact structure 118d in the fourth group 122d contacts the fourth signal conductive layer 116d, and at least one fourth ground contact structure 119d in the fourth group 122d contacts the fourth ground conductive layer 117d.

In some implementations, the second group 122b of the second signal contact structures 118b and the second ground contact structures 119b extends from the semiconductor structure 104a through the substrate 114 of the semiconductor structure 104a and into the semiconductor structure 104b along the Z direction. The second ground contact structures 119b in the second group 122b are evenly spaced among the second signal contact structures 118b in the second group 122b. At least one second signal contact structure 118b in the second group 122b contacts the second signal conductive layer 116b, and at least one second ground contact structure 119b in the second group 122b contacts the second ground conductive layer 117b.

The signal contact structures 118 and the ground contact structures 119 in the groups 122 of the semiconductor device 100b are arranged in an array. In the array, each signal contact structure 118 of the signal contact structures 118 is adjacent to a corresponding ground contact structure 119 of the ground contact structures 119, where a distance between the signal contact structure 118 and the corresponding ground contact structure 119 equals a pitch size of the array. In some implementations, the pitch size of the array is in a range between 0.5 micrometers (µm) and 10 µm, and a size of each of the signal contact structures 118 or each of the ground contact structures 119 in the array along the Y direction is between 0.5 µm and 10 µm.

It is understood that the example semiconductor device 100b as shown in FIG. 1B is for illustration purpose and is not intended to be construed in a limiting sense. For example, the semiconductor structures 104 stacked on top of each other is not limited to 4 structures and any number of semiconductor structures 104 can be stacked on top of each other in the semiconductor device 100b. For each of the semiconductor structures 104, the semiconductor device 100b includes the signal contact structures 118 and ground contact structures 119 that contact the corresponding signal conductive layer 116 and the ground conductive layer 117 of each of the semiconductor structures 104.

In some implementations, as shown in FIG. 1B, the substrates 114 of the semiconductor structures 104a – 104c can include dielectric structures 124 that are formed before forming the first contact holes and the second contact holes. The dielectric structures 124 of the semiconductor structures 104a – 104c can be formed by etching a portion of the substrates 114 of the semiconductor structures 104a – 104c and filling the etching portion with a dielectric material (e.g., SiO₂). The semiconductor structures 104a – 104d are then bonded on top of each other through the bonding structures 106. In some implementations, the signal contact structures 118 and the ground contact structures 119 can be formed by etching a first portion of the semiconductor structures 104a – 104d to form a first contact holes and etching a second portion of the semiconductor structures 104a – 104d to from a second contact holes, where a portion of the first contact holes and a portion of the second contact holes extend through the dielectric structures 124. For example, the substrate 114 of the semiconductor structure 104a can include the first dielectric structure 124a and a portion of the first contact holes and the second contact holes extend through the first dielectric structure 124a along the Z direction.

In some implementations, the dielectric structures 124 in the substrates 114 of the semiconductor structures 104a – 104d can include a same dielectric material (e.g., SiO₂) as the dielectric filling of the semiconductor structures 104a – 104d. The same dielectric material can help to simplify the etching process when forming the first contact holes and the second contact holes of the semiconductor device 100b compared to the forming of the first contact holes and the second contact holes of the semiconductor device 100a of FIG. 1A. For example, one etching process with a first etching can be used to etch through the dielectric filling of the first semiconductor structure 104a, the first dielectric structure 124a of the substrate 114 of the first semiconductor structure 104a, and into the dielectric filling of the second semiconductor structure 104b to form the first contact holes that are in contact with the second signal conductive layer 116b of the semiconductor structure 104b.

The first contact holes and the second contact holes are spaced from each other along the Y direction. The first contact holes are in contact with the signal conductive layers 116 of the corresponding semiconductor structures 104a – 104d. The second contact holes are in contact with the ground conductive layers 117 of the corresponding semiconductor structures 104a – 104d. The signal structures 118 are formed by filling a first conductive material in the first contact holes. The ground contact structures 119 are formed by filling a second conductive material in the second contact holes. In some implementations, the first conductive material can be any conductive material including, but not limited to, W, Co, Cu, Al, doped silicon, silicides, or any combination thereof. The second conductive material can be any conductive material including, but not limited to, W, Co, Cu, Al, doped silicon, silicides, or any combination thereof. In some implementations, the first conductive material can be same as the second conductive material. For example, the first conductive material and the second conductive material both can be W.

FIG. 1C illustrates a top view of the example semiconductor device 100c, according to some aspects of the present disclosure. In some implementations, the device region 126 and the connection region 128 can be arranged in an array. The device region 126 can be the device region 126 of the semiconductor devices 100a – 100b of FIGS. 1A – 1B and the connection region 128 can be the connection region 128 of the semiconductor devices 100a – 100b of FIGS. 1A – 1B. For example, as shown in FIG. 1C, a first line of the array can include two device regions 126 along the Y direction and one connection region 128 between the two device regions 126 along the Y direction. In some implementations, as shown in FIG. 1C, the fist lines of the array of the device regions 126 and the connection region 128 can be stacked along the X direction to from a column of the array. While FIG. 1C shows an example arrangement of the line of the array of device region(s) 126 and connection region(s) 128, any other suitable arrangements are possible. In some implementations, semiconductor device 100c can include one device region 126 and one connection region 128 adjacent to each other along the Y direction. In some implementations, semiconductor device 100c can include two connection regions 128 arranged along the Y direction and one device region 126 between the two connection regions 128 along the Y direction. In some implementations, semiconductor device 100c can include a first connection region 128, a second connection region 128, and a device region 126 arranged along the Y direction. The first connection region 128 can be in the center of the semiconductor device 100c, and the second connection region 128can be on one side (e.g., on the left side) of the first connection region 128. The device region 126 can be on another side (e.g., on the right side) of the first connection region 128. In some implementations, the semiconductor device 100c can include one device region 126 and one connection region 128 adjacent to each other along the X direction.

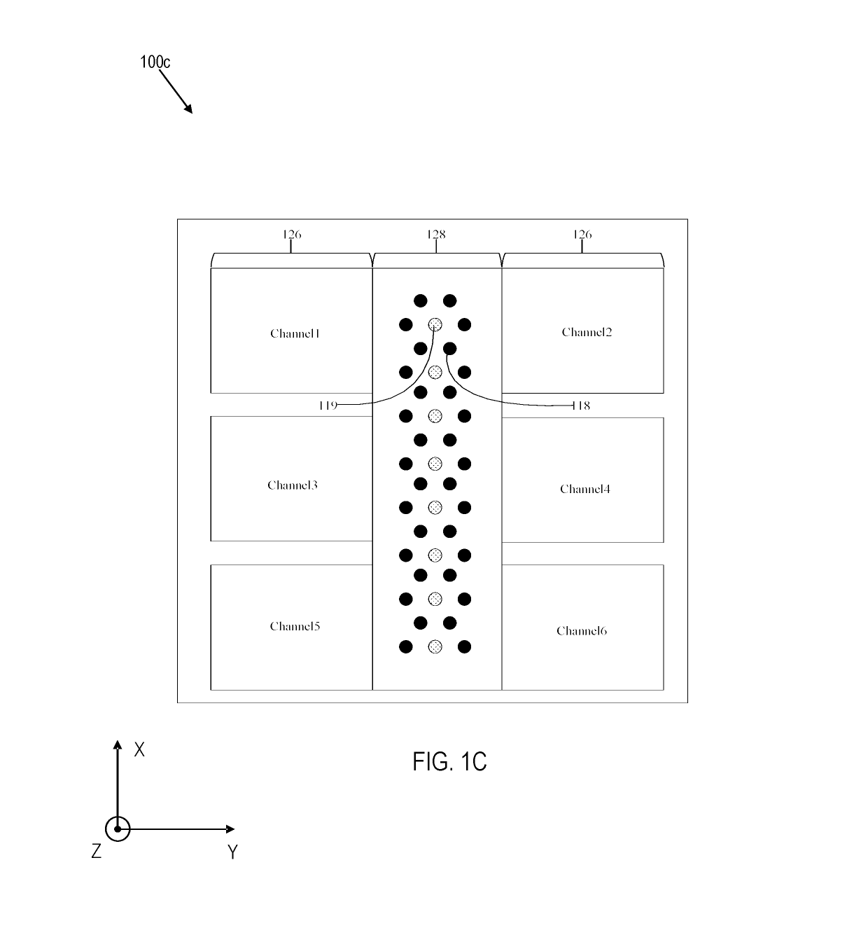

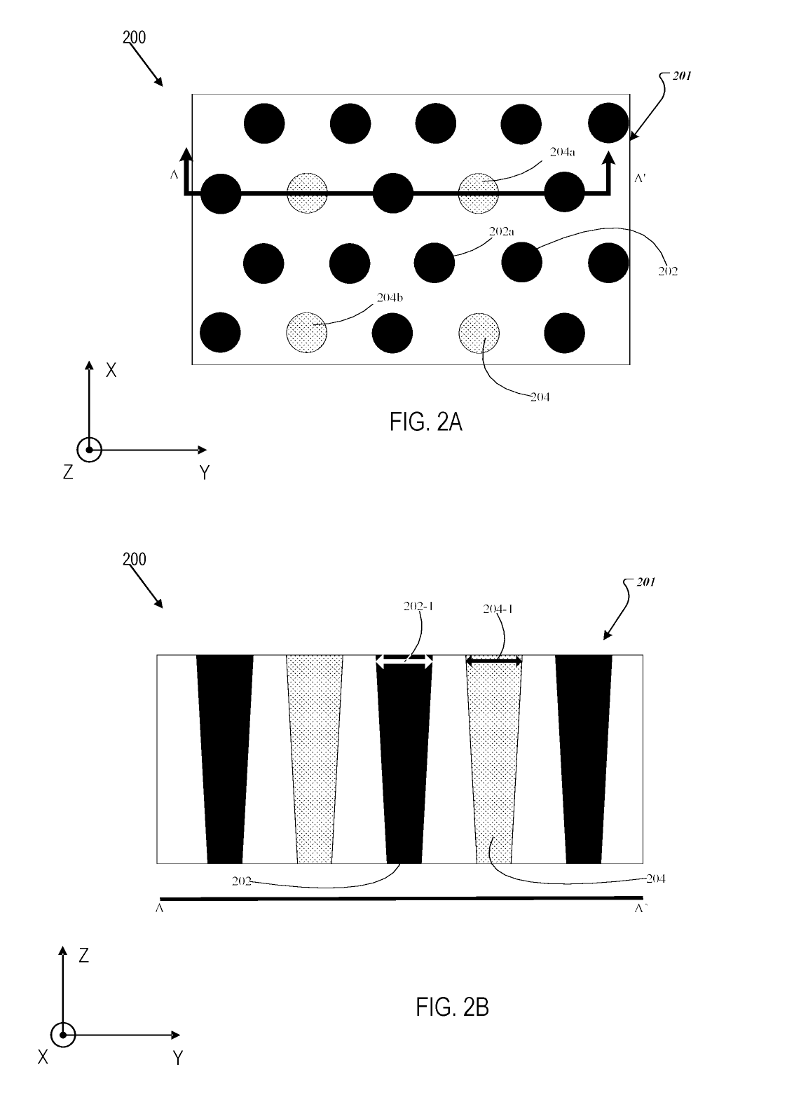

FIG. 2A illustrates a top view of an example semiconductor device 200, according to some aspects of the present disclosure. The semiconductor device 200 can be a top view of the connection regions 128 of the semiconductor devices 100a – 100b of FIGS. 1A – 1B.

As shown in FIG. 2A, the semiconductor device 200 can include signal contact structures 202 and ground contact structures 204 that are arranged in an array 201. In some implementations, the signal contact structures 202 of the semiconductor device 200 can be similar to, or same as, the signal contact structures 118 of the semiconductor devices 100a – 100b of FIGS. 1A – 1B. The ground contact structures 204 of the semiconductor device 200 can be similar to, or same as, the ground contact structures 119 of the semiconductor devices 100a – 100b of FIGS. 1A – 1B. Although the examples of FIGS. 1A-1B only show one signal contact structure and one ground contact structure in each group (e.g., the signal contact structure 118a and the ground contact structure 119a in the group 122a), it is understood that each group can include multiple signal contact structures and multiple ground contact structures. The arrangements of signal contact structures and ground contact structures as shown in FIGS. 2A-4C can be applied to each group in FIGS. 1A-1B (e.g., group 122a, 122b, 122c, or 122d). Alternatively, in some implementations, the arrangements of signal contact structures and ground contact structures as shown in FIGS. 2A-4C can be applied to a combination of multiple groups in FIGS. 1A-1B (e.g., a combination of groups 122a, 122b, 122c, and 122d). As shown in FIG. 2A, the array 201 of the signal contact structures 202 and the ground contact structures 204 can have rows extend along the Y direction and columns extend along the X direction. In some implementations, for each group, each signal contact structure in the group is adjacent to at least one ground contact structure. In the present disclosure, a signal contact structure being adjacent to a ground contact structure can be interpreted as that a distance between the signal contact structure and the ground contact structure is the minimum distance between two contact structures in the array. For example, as shown in FIG. 2A, signal contact structure 202a is adjacent to ground contact structure 204a, but is not adjacent to ground contact structure 204b, because a distance between the signal contact structure 202a and ground contact structure 204a is the minimum distance between two contacts structures in the array 201 but a distance between signal contact structure 202a and ground contact structure 204b is larger than the minimum distance between two contact structures in the array 201. In some implementations, the minimum distance between two contact structures in the array 201 equals a pitch size of the array 201. In some implementations, each signal contact structure in a combination of multiple groups in the array 201 is adjacent to at least one ground contact structure. In some implementations, each of the signal contact structures 202 in the array 201 is adjacent to a corresponding ground contact structure 204 in the array 201. A distance between the signal contact structures 202 in the array 201 and the corresponding ground contact structure 204 in the array 201 equals a pitch size of the array. In some implementations, the pitch size of the array is in a range between 0.5 micrometers (µm) and 10 µm. In some implementations, each signal contact structure in the array is adjacent to a same number of ground contact structures in the array. For example, as shown in FIG. 2A, each signal contact structure in the array 201 is adjacent to two ground contact structures.

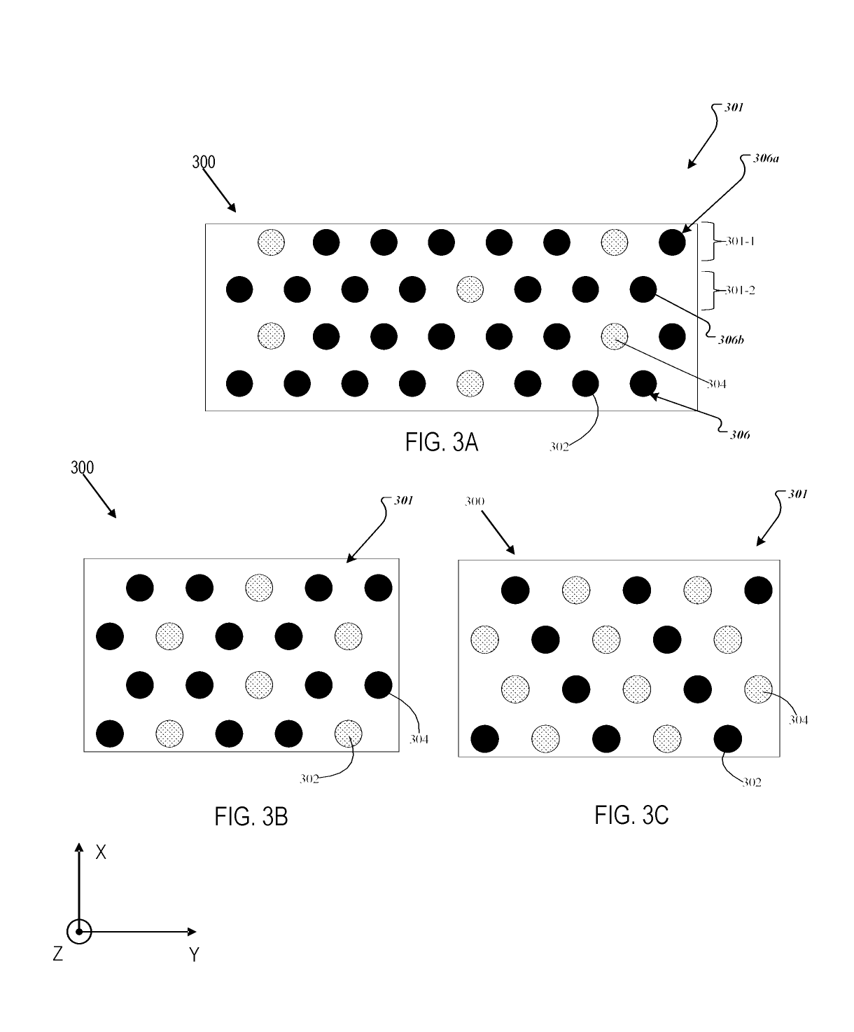

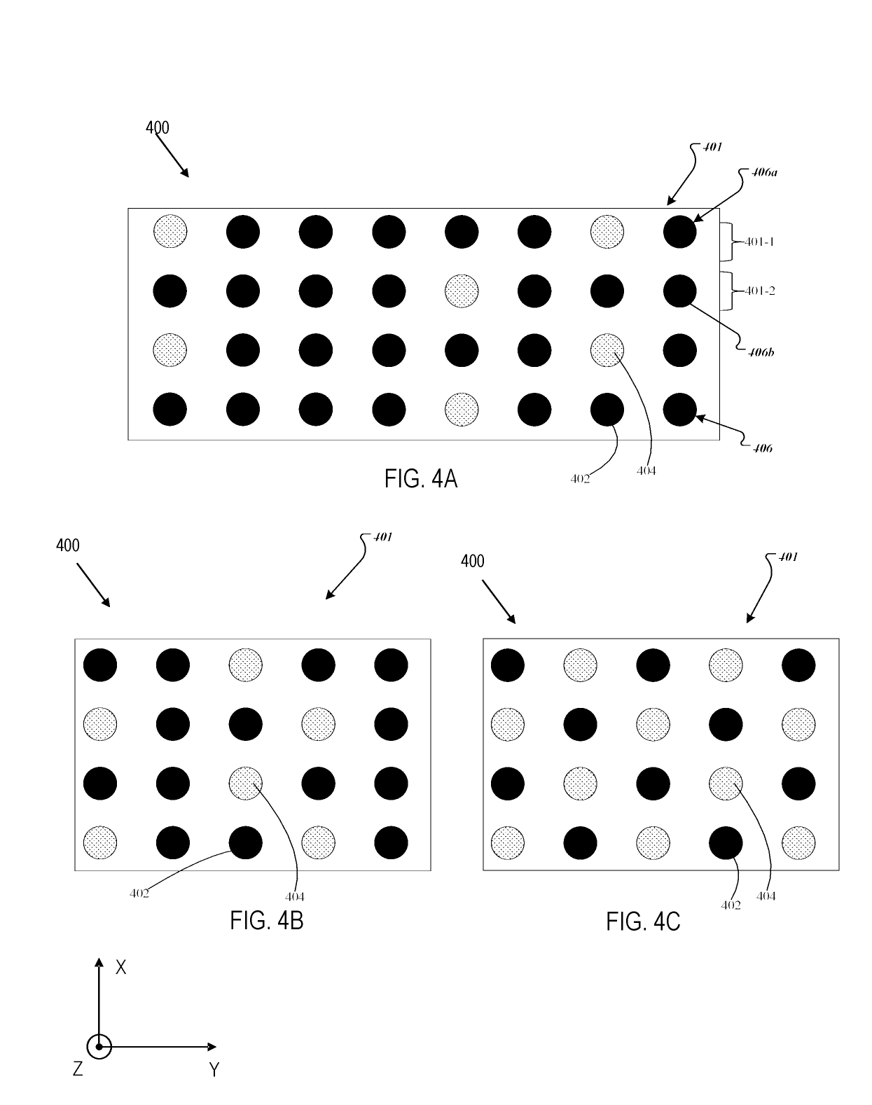

FIG. 2B illustrates a cross-sectional view of the semiconductor device 200 along the cut line AA’, according to some aspects of the present disclosure. The cut line AA’ can be along a row of the array 201 of FIG. 2A. In some implementations, as shown in FIG. 2B, the ground contact structures 204 are evenly spaced among the signal contact structures 202 along the row of the array 201. In some implementations, a same number of the signal contact structures 202 are between any two adjacent ground contact structures 204 along the Y direction. In some implementations, the number of the signal contact structures 202 between any two adjacent ground contact structures 204 along the Y direction is an integer between one and five (as shown in the array in FIGS. 3A – 3C or the array in FIGS. 4A – 4C). In some implementations, a size of a first end 202-1 of each of the signal contact structures 202 or a first end 204-1 of each of the ground contact structures 204 in the array 201 along the Y direction is between 0.5 µm and 10 µm.

FIGS. 3A – 3C illustrates top views of example semiconductor device 300, according to some aspects of the present disclosure. The semiconductor device 300 can be a demonstration of the array of the signal contact structures 118 and the ground contact structures 119 of the connection regions 128 of the semiconductor devices 100a – 100b of FIGS. 1A – 1B.

As shown in FIGS. 3A-3C, the semiconductor device 300 can include signal contact structures 302 and ground contact structures 304. In some implementations, the signal contact structures 302 of the semiconductor device 300 can be similar to, or same as, the signal contact structures 118 of the semiconductor devices 100a – 100b of FIGS. 1A – 1B or the signal contact structures 202 of the semiconductor device 200 of FIG. 2A. The ground contact structures 304 of the semiconductor device 200 can be similar to, or same as, the ground contact structures 119 of the semiconductor devices 100a – 100b of FIGS. 1A – 1B or the ground contact structures 204 of the semiconductor device 200 of FIG. 2A.

In some implementations, the signal contact structures 302 and the ground contact structures 304 can be arranged in an array 301 that have rows extending along the Y direction and columns extending along the X direction. In some implementations, the array 301 of the semiconductor device can be a part of the connection region 128 of the semiconductor devices 100a of FIG. 1A, where the array 301 of the signal contact structures 302 and the ground contact structures 304 can be separated into multiple groups 306 that are connected to the corresponding signal conductive layers 116 and ground conductive layers 117 of each of the semiconductor structures 104a – 104d of the semiconductor device 100a. For example, as shown in FIG. 3A, a first group 306a of the signal contact structures 302 and the ground contact structures 304 can include a first row 301-1 of the array 301, where the signal contact structures 302 in the first group 306a are connected to the first signal conductive layers 116a of the semiconductor structure 104a and the ground contact structures 304 in the first group 306a are connected to the first ground conductive layers 117a of the semiconductor structure 104a. A second group 306b of the signal contact structures 302 and the ground contact structures 304 can include a second row 301-2 of the array 301, where the signal contact structures 302 in the second group 306b are connected to the second signal conductive layers 116b of the semiconductor structure 104b and the ground contact structures 304 in the second group 306b are connected to the first ground conductive layers 117a of the semiconductor structure 104b.

In some implementations, the array 301 of the signal contact structures 302 and the ground contact structures 304 of the semiconductor device 300 can belong to a same group 306 that connects to one of the semiconductor structures 104a – 104d of the semiconductor device 100a. For example, as shown in FIG. 3A, all of the signal contact structures 302 in the array 301 can be connected to the first signal conductive layers 116a of the semiconductor structure 104a and all of the ground contact structures 304 in the array 301 can be connected to the first ground conductive layer 117a of the semiconductor structure 104a.

In some implementations, as shown in FIGS. 3A – 3C, the rows of the array 301 are offset along the X direction. For example, each of the signal contact structures 302 and the ground contact structures 304 of the first group 306a is between either two adjacent ones of the signal contact structure 302 or one of the signal contact structures 302 and one of the ground contact structures 304 of the second group 306b along the Y direction.

In some implementations, a same number of the signal contact structures 302 are between any two adjacent ground contact structures 304 in each of the rows of the array 301. In some implementations, the number is an integer between one and five. For example, as shown in FIG. 3A, the number of the signal contact structures 302 that are between any two adjacent ground contact structures 304 in each of the rows of the array 301 is five. As shown in FIG. 3B, the number of the signal contact structures 302 that are between any two adjacent ground contact structures 304 in each of the rows of the array 301 is two. As shown in FIG. 3C, the number of the signal contact structures 302 that are between any two adjacent ground contact structures 304 in each of the rows of the array 301 is one.

FIGS. 4A – 4C illustrates top views of example semiconductor device 400, according to some aspects of the present disclosure. The semiconductor device 400 can be a demonstration of the array of the signal contact structures 118 and the ground contact structures 119 of the connection regions 128 of the semiconductor devices 100a – 100b of FIGS. 1A – 1B.

As shown in FIGS. 4A-4C, the semiconductor device 400 can include signal contact structures 402 and ground contact structures 404. In some implementations, the signal contact structures 402 of the semiconductor device 400 can be similar to, or same as, the signal contact structures 118 of the semiconductor devices 100a – 100b of FIGS. 1A – 1B or the signal contact structures 202 of the semiconductor device 200 of FIG. 2A. The ground contact structures 404 of the semiconductor device 400 can be similar to, or same as, the ground contact structures 119 of the semiconductor devices 100a – 100b of FIGS. 1A – 1B or the ground contact structures 204 of the semiconductor device 200 of FIG. 2A.

In some implementations, the signal contact structures 402 and the ground contact structures 404 can be arranged in an array 401 that have rows extending along the Y direction and columns extending along the X direction. In some implementations, the array 401 of the semiconductor device can be a part of the connection region 128 of the semiconductor devices 100a of FIG. 1A, where the array 401 of the signal contact structures 402 and the ground contact structures 404 can be separated into multiple groups 406 that are connected to the corresponding signal conductive layers 116 and ground conductive layers 117 of each of the semiconductor structures 104a – 104d of the semiconductor device 100a. For example, as shown in FIG. 4A, a first group 406a of the signal contact structures 402 and the ground contact structures 404 can include a first row 401-1 of the array 401, where the signal contact structures 402 in the first group 406a are connected to the first signal conductive layers 116a of the semiconductor structure 104a and the ground contact structures 404 in the first group 406a are connected to the first ground conductive layers 117a of the semiconductor structure 104a. A second group 406b of the signal contact structures 402 and the ground contact structures 404 can include a second row 401-2 of the array 401, where the signal contact structures 402 in the second group 406b are connected to the second signal conductive layers 116b of the semiconductor structure 104b and the ground contact structures 404 in the second group 406b are connected to the first ground conductive layers 117a of the semiconductor structure 104b.

In some implementations, the array 401 of the signal contact structures 402 and the ground contact structures 404 of the semiconductor device 400 can belong to a same group 406 that connects to one of the semiconductor structures 104a – 104d of the semiconductor device 100a. For example, all of the signal contact structures 402 in the array 401 can be connected to the first signal conductive layers 116a of the semiconductor structure 104a and all of the ground contact structures 404 in the array 401 can be connected to the first ground conductive layer 117a of the semiconductor structure 104a.

In some implementations, as shown in FIGS. 4A – 4C, the rows of the array 401 are aligned in the X direction. For example, as shown in FIG. 4A, each of the signal contact structures 402 or each of the ground contact structures 404 in the first group 406a is aligned with one of the signal contact structures 402 or one of the ground contact structures 404 in the second group 406b (e.g., along the X direction).

In some implementations, a same number of the signal contact structures 402 are between any two adjacent ground contact structures 404 in each of the rows of the array 401. In some implementations, the number is an integer between one and five. For example, as shown in FIG. 4A, the number of the signal contact structures 402 that are between any two adjacent ground contact structures 404 in each of the rows of the array 401 is five. As shown in FIG. 4B, the number of the signal contact structures 402 that are between any two adjacent ground contact structures 404 in each of the rows of the array 401 is two. As shown in FIG. 4C, the number of the signal contact structures 402 that are between any two adjacent ground contact structures 404 in each of the rows of the array 401 is one.

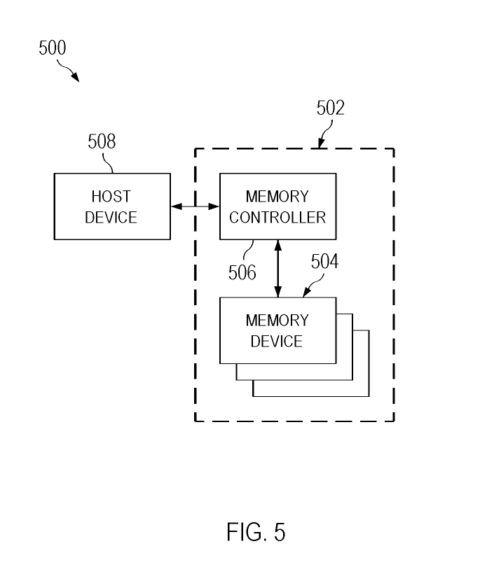

FIG. 5 illustrates a block diagram of a system 500 having one or more semiconductor devices (e.g., memory devices), according to one or more implementations of the present disclosure. The system 500 can be a mobile phone, a desktop computer, a laptop computer, a tablet, a vehicle computer, a gaming console, a printer, a positioning device, a wearable electronic device, a smart sensor, a virtual reality (VR) device, an argument reality (AR) device, or any other suitable electronic devices having storage therein. As shown in FIG. 5, the system 500 can include a host device 508 and a memory system 502 having one or more 3D memory devices 504 and a memory controller 506. Host device 508 can include a processor of an electronic device, such as a central processing unit (CPU), or a system-on-chip (SoC), such as an application processor (AP). Host device 508 can be configured to send or receive data to or from the one or more 3D memory devices 504.

A 3D memory device 504 can be any 3D memory device disclosed herein, such as a 3D memory device depicted in FIGS. 1A - 1B. In some implementations, a 3D memory device 504 includes at least one DRAM memory. Memory controller 506 (a.k.a., a controller circuit) is coupled to 3D memory device 504 and host device 508. Consistent with implementations of the present disclosure, 3D memory device 504 can include a plurality of conductive interconnections through a cover layer that ar1e in contact with conductive pads in a conductive pad layer, and memory controller 506 can be coupled to 3D memory device 504 through at least one of the plurality of conductive interconnections. Memory controller 506 is configured to control 3D memory device 504. For example, memory controller 506 may be configured to operate a plurality of channel structures via word lines. Memory controller 506 can manage data stored in 3D memory device 504 and communicate with host device 508.

In some implementations, memory controller 506 is designed/configured for operating in a low duty-cycle environment like secure digital (SD) cards, compact Flash (CF) cards, universal serial bus (USB) Flash drives, or other media for use in electronic devices, such as personal computers, digital cameras, mobile phones, etc. In some implementations, memory controller 506 is designed/configured for operating in a high duty cycle environment SSDs or embedded multi-media-cards (eMMCs) used as data storage for mobile devices, such as smartphones, tablets, laptop computers, etc., and enterprise storage arrays. Memory controller 506 can be configured to control operations of 3D memory device 504, such as read, erase, and program (or write) operations. Memory controller 506 can also be configured to manage various functions with respect to the data stored or to be stored in 3D memory device 504 including, but not limited to bad-block management, garbage collection, logical-to-physical address conversion, wear leveling, etc. In some implementations, memory controller 506 is further configured to process error correction codes (ECCs) with respect to the data read from or written to 3D memory device 504. Any other suitable functions may be performed by memory controller 506 as well, for example, formatting 3D memory device 504.

Memory controller 506 can communicate with an external device (e.g., host device 508) according to a particular communication protocol. For example, memory controller 506 may communicate with the external device through at least one of various interface protocols, such as a USB protocol, an MMC protocol, a peripheral component interconnection (PCI) protocol, a PCIexpress (PCI-E) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol, a Firewire protocol, etc.

Memory controller 506 and one or more 3D memory devices 504 can be integrated into various types of storage devices, for example, be included in the same package, such as a universal Flash storage (UFS) package or an eMMC package. That is, memory system 502 can be implemented and packaged into different types of end electronic products. In one example as shown in FIG. 5, memory controller 506 and a single 3D memory device 504 may be integrated into a memory card 502. Memory card 502 can include a PC card (PCMCIA, personal computer memory card international association), a CF card, a smart media (SM) card, a memory stick, a multimedia card (MMC, RS-MMC, MMCmicro), an SD card (SD, miniSD, microSD, SDHC), a UFS, etc.

Implementations of the subject matter and the actions and operations described in this present disclosure can be implemented in digital electronic circuitry, in tangibly-embodied computer software or firmware, in computer hardware, including the structures disclosed in this present disclosure and their structural equivalents, or in combinations of one or more of them. Implementations of the subject matter described in this present disclosure can be implemented as one or more computer programs, e.g., one or more modules of computer program instructions, encoded on a computer program carrier, for execution by, or to control the operation of, data processing apparatus. The carrier may be a tangible non-transitory computer storage medium. Alternatively, or in addition, the carrier may be an artificially-generated propagated signal, e.g., a machine-generated electrical, optical, or electromagnetic signal, that is generated to encode information for transmission to suitable receiver apparatus for execution by a data processing apparatus. The computer storage medium can be or be part of a machine-readable storage device, a machine-readable storage substrate, a random or serial access memory device, or a combination of one or more of them. A computer storage medium is not a propagated signal.

It is noted that references in the present disclosure to “one embodiment,” “an embodiment,” “an example embodiment,” “some implementations,” “some implementations,” etc., indicate that the embodiment described can include a particular feature, structure, or characteristic, but every embodiment can not necessarily include the particular feature, structure, or characteristic. Moreover, such phrases do not necessarily refer to the same embodiment. Further, when a particular feature, structure or characteristic is described in connection with an embodiment, it would be within the knowledge of a person skilled in the pertinent art to affect such feature, structure or characteristic in connection with other implementations whether or not explicitly described.

In general, terminology can be understood at least in part from usage in context. For example, the term “one or more” as used herein, depending at least in part upon context, can be used to describe any feature, structure, or characteristic in a singular sense or can be used to describe combinations of features, structures or characteristics in a plural sense. Similarly, terms, such as “a,” “an,” or “the,” again, can be understood to convey a singular usage or to convey a plural usage, depending at least in part upon context. In addition, the term “based on” can be understood as not necessarily intended to convey an exclusive set of factors and may, instead, allow for existence of additional factors not necessarily expressly described, again, depending at least in part on context.

It should be readily understood that the meaning of “on,” “above,” and “over” in the present disclosure should be interpreted in the broadest manner such that “on” not only means “directly on” something, but also includes the meaning of “on” something with an intermediate feature or a layer therebetween. Moreover, “above” or “over” not only means “above” or “over” something, but can also include the meaning it is “above” or “over” something with no intermediate feature or layer therebetween (i.e., directly on something).

Further, spatially relative terms, such as “beneath,” “below,” “lower,” “above,” “upper,” and the like, can be used herein for ease of description to describe one element or feature’s relationship to another element(s) or feature(s) as illustrated in the figures. The spatially relative terms are intended to encompass different orientations of the device in use or process step in addition to the orientation depicted in the figures. The apparatus can be otherwise oriented (rotated 90 degrees or at other orientations) and the spatially relative descriptors used herein can likewise be interpreted accordingly.

As used herein, the term “substrate” refers to a material onto which subsequent material layers are added. The substrate includes a “top” surface and a “bottom” surface. The top surface of the substrate is typically where a semiconductor device is formed, and therefore the semiconductor device is formed at a top side of the substrate unless stated otherwise. The bottom surface is opposite to the top surface and therefore a bottom side of the substrate is opposite to the top side of the substrate. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically noN+ conductive material, such as a glass, a plastic, or a sapphire wafer.

As used herein, the term “layer” refers to a material portion including a region with a thickness. A layer has a top side and a bottom side where the bottom side of the layer is relatively close to the substrate and the top side is relatively away from the substrate. A layer can extend over the entirety of an underlying or overlying structure, or can have an extent less than the extent of an underlying or overlying structure. Further, a layer can be a region of a homogeneous or inhomogeneous continuous structure that has a thickness less than the thickness of the continuous structure. For example, a layer can be located between any set of horizontal planes between, or at, a top surface and a bottom surface of the continuous structure. A layer can extend horizontally, vertically, and/or along a tapered surface. A substrate can be a layer, can include one or more layers therein, and/or can have one or more layer thereupon, thereabove, and/or therebelow. A layer can include multiple layers. For example, an interconnect layer can include one or more conductive and contact layers (in which contacts, interconnect lines, and/or vertical interconnect accesses (VIAs) are formed) and one or more dielectric layers.

As used herein, the term “nominal/nominally” refers to a desired, or target, value of a characteristic or parameter for a component or a process step, set during the design phase of a product or a process, together with a range of values above and/or below the desired value. As used herein, the range of values can be due to slight variations in manufacturing processes or tolerances. As used herein, the term “about” indicates the value of a given quantity that can vary based on a particular technology node associated with the subject semiconductor device. Based on the particular technology node, the term “about” can indicate a value of a given quantity that varies within, for example, 10-30% of the value (e.g., .+-.10%, .+-.20%, or .+-.30% of the value).

In the present disclosure, the term “horizontal/horizontally/lateral/laterally” means nominally parallel to a lateral surface of a substrate, and the term “vertical” or “vertically” means nominally perpendicular to the lateral surface of a substrate.

As used herein, the term “3D memory” refers to a three-dimensional (3D) semiconductor device with vertically oriented strings of memory cell transistors (referred to herein as “memory strings,” such as NAND strings) on a laterally-oriented substrate so that the memory strings extend in the vertical direction with respect to the substrate.

The present disclosure provides many different implementations, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include implementations in which the first and second features may be in direct contact, and may also include implementations in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various implementations and/or configurations discussed.

The foregoing description of the specific implementations can be readily modified and/or adapted for various applications. Therefore, such adaptations and modifications are intended to be within the meaning and range of equivalents of the disclosed implementations, based on the teaching and guidance presented herein.

While the present disclosure contains many specific implementation details, these should not be construed as limitations on the scope of what is being claimed, which is defined by the claims themselves, but rather as descriptions of features that may be specific to particular implementations of particular inventions. Certain features that are described in this present disclosure in the context of separate implementations can also be implemented in combination in a single embodiment. Conversely, various features that are described in the context of a single embodiment can also be implemented in multiple implementations separately or in any suitable sub-combination. Moreover, although features may be described above as acting in certain combinations and even initially be claimed as such, one or more features from a claimed combination can in some cases be excised from the combination, and the claim may be directed to a sub-combination or variation of a sub-combination.

Similarly, while operations are depicted in the drawings and recited in the claims in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system modules and components in the implementations described above should not be understood as requiring such separation in all implementations, and it should be understood that the described program components and systems can generally be integrated together in a single software product or packaged into multiple software products.

Particular implementations of the subject matter have been described. Other implementations also are within the scope of the following claims. For example, the actions recited in the claims can be performed in a different order and still achieve desirable results. As one example, the processes depicted in the accompanying figures do not necessarily require the particular order shown, or sequential order, to achieve desirable results. In some cases, multitasking and parallel processing may be advantageous.

The breadth and scope of the present disclosure should not be limited by any of the above-described exemplary implementations, but should be defined only in accordance with the following claims and their equivalents.

What is claimed is:

1. A semiconductor device, comprising:
a first semiconductor structure and a second semiconductor structure stacked along a first direction, wherein the first semiconductor structure comprises a first ground conductive layer and a first signal conductive layer, and the second semiconductor structure comprises a second ground conductive layer and a second signal conductive layer;
a first group of signal contact structures and ground contact structures, wherein the first group extends into the first semiconductor structure along the first direction, at least one signal contact structure in the first group contacts the first signal conductive layer, and at least one ground contact structure in the first group contacts the first ground conductive layer; and
a second group of signal contact structures and ground contact structures, wherein the second group extends into the second semiconductor structure along the first direction, at least one signal contact structure in the second group contacts the second signal conductive layer, and at least one ground contact structure in the second group contacts the second ground conductive layer, and wherein:
at least one group of the first group or the second group comprises signal contact structures and ground contact structures arranged in an array;
the array comprises first signal contact structures and first ground contact structures arranged along a first line extending in a second direction perpendicular to the first direction; and
each of the first signal contact structures is adjacent to a corresponding ground contact structure in the array.

2. The semiconductor device of claim 1, wherein each signal contact structure in the array is adjacent to a corresponding ground contact structure in the array, wherein a distance between the signal contact structure in the array and the corresponding ground contact structure in the array equals a pitch size of the array.

3. The semiconductor device of claim 2, wherein each signal contact structure in the array is adjacent to a same number of ground contact structures in the array.

4. The semiconductor device of claim 1, wherein the first ground contact structures are evenly spaced among the first signal contact structures.

5. The semiconductor device of claim 1, wherein the at least one of the first semiconductor structure or the second semiconductor structure is a dynamic random-access memory (DRAM) device.

6. The semiconductor device of claim 5, wherein the DRAM device comprises an array structure and a peripheral structure, the array structure comprises an array of DRAM cells, at least one DRAM cell of the array structure comprises a transistor and a capacitor, and the peripheral structure comprises a peripheral circuit configured to control the array of DRAM cells.

7. The semiconductor device of claim 2, wherein the pitch size is in a range between 0.5 micrometers (µm) and 10 µm, and a size of each signal contact structure or each ground contact structure in the array along the second direction is between 0.5 µm and 10 µm.

8. The semiconductor device of claim 1, wherein a same number of first signal contact structures are between any two adjacent first ground contact structures along the second direction.

9. The semiconductor device of claim 8, wherein the number is an integer between one and five.

10. The semiconductor device of claim 1, wherein the array further comprises second signal contact structures and second ground contact structures arranged along a second line extending in the second direction, the second ground contact structures are evenly spaced among the second signal contact structures, and the second line is adjacent to the first line along a third direction perpendicular to the first direction and the second direction.

11. The semiconductor device of claim 10, wherein each of the first signal contact structures or each of the first ground contact structures is aligned with one of the second signal contact structures or one of the second ground contact structures along the third direction.

12. The semiconductor device of claim 10, wherein each of the first signal contact structures and the first ground contact structures is between either two adjacent ones of the second signal contact structures or one of the second signal contact structures and one of the second ground contact structures along the second direction.

13. The semiconductor device of claim 1, further comprising:
a third semiconductor structure comprising a third ground conductive layer and a third signal conductive layer, wherein the second semiconductor structure is between the first semiconductor structure and the third semiconductor structure along the first direction; and
a third group of signal contact structures and ground contact structures, wherein the third group extends into the third semiconductor structure along the first direction, at least one signal contact structure in the third group contacts the third signal conductive layer, at least one ground contact structure in the third group contacts the third ground conductive layer, the third group comprises third signal contact structures and third ground contact structures arranged along a third line extending in the second direction, and each of the third signal contact structures is adjacent to at least one ground contact structure in the third group.

14. The semiconductor device of claim 13, further comprising:
a first bonding structure between the first semiconductor structure and the second semiconductor structure, wherein the first semiconductor structure and the second semiconductor structure are bonded through the first bonding structure; and
a second bonding structure between the second semiconductor structure and the third semiconductor structure, wherein the second semiconductor structure and the third semiconductor structure are bonded through the second bonding structure.

15. A semiconductor device, comprising:
a first semiconductor structure and a second semiconductor structure stacked along a first direction, wherein the first semiconductor structure comprises a first substrate, a first ground conductive layer and a first signal conductive layer, the first substrate comprises a first dielectric structure and a semiconductor material adjacent to the first dielectric structure, and the second semiconductor structure comprises a second ground conductive layer and a second signal conductive layer;
a first group of signal contact structures and ground contact structures, wherein the first group extends into the first semiconductor structure along the first direction, at least one signal contact structure in the first group is adjacent to a corresponding ground contact structure in the first group, at least one signal contact structure in the first group contacts the first signal conductive layer, and at least one ground contact structure in the first group contacts the first ground conductive layer; and
a second group of signal contact structures and ground contact structures, wherein the second group extends through the first dielectric structure and into the second semiconductor structure along the first direction, at least one signal contact structure in the second group is adjacent to a corresponding ground contact structure in the second group, at least one signal contact structure in the second group contacts the second signal conductive layer, and at least one ground contact structure in the second group contacts the second ground conductive layer.

16. The semiconductor device of claim 15, wherein the second semiconductor structure comprises a second substrate, the second substrate comprises a second dielectric structure and a semiconductor material adjacent to the second dielectric structure, and the semiconductor device further comprises:
a third semiconductor structure comprising a third ground conductive layer and a third signal conductive layer, wherein the second semiconductor structure is between the first semiconductor structure and the third semiconductor structure along the first direction; and
a third group of signal contact structures and ground contact structures, wherein the third group extends from the first semiconductor structure through the first dielectric structure and the second dielectric structure and into the third semiconductor structure along the first direction, at least one signal contact structure in the third group is adjacent to a corresponding ground contact structure in the third group, at least one signal contact structure in the third group contacts the third signal conductive layer, and at least one ground contact structure in the third group contacts the third ground conductive layer.

17. The semiconductor device of claim 16, wherein the first dielectric structure and the second dielectric structure have a same size along a second direction perpendicular to the first direction and are aligned along the first direction, the semiconductor material in the first substrate is adjacent to the first dielectric structure along the second direction, and the semiconductor material in the second substrate is adjacent to the second dielectric structure along the second direction.

18. The semiconductor device of claim 15, wherein the first semiconductor structure and the second semiconductor structure are bonded through a dielectric bonding structure.

19. A semiconductor device, comprising:
a first semiconductor structure and a second semiconductor structure stacked along a first direction, wherein the first semiconductor structure comprises a first substrate, a first ground conductive layer and a first signal conductive layer, and the second semiconductor structure comprises a second ground conductive layer and a second signal conductive layer;
a first group of signal contact structures and ground contact structures, wherein the first group extends into the first semiconductor structure along the first direction, at least one signal contact structure in the first group is adjacent to a corresponding ground contact structure in the first group, at least one signal contact structure in the first group contacts the first signal conductive layer, and at least one ground contact structure in the first group contacts the first ground conductive layer; and
a second group of signal contact structures and ground contact structures, wherein the second group extends through the first substrate and into the second semiconductor structure along the first direction, at least one signal contact structure in the second group is adjacent to a corresponding ground contact structure in the second group, at least one signal contact structure in the second group contacts the second signal conductive layer, and at least one ground contact structure in the second group contacts the second ground conductive layer.

20. The semiconductor device of claim 19, wherein the signal contact structures and the ground contact structures in at least one of the first group or the second group are arranged in an array, each signal contact structure of the signal contact structures is adjacent to a corresponding ground contact structure of the ground contact structures, wherein a distance between the signal contact structure and the corresponding ground contact structure equals a pitch size of the array.
